(19) United States
(12) Patent Application Publication
(10) Pub. No.: US 2007/0103207 A1
(43) Pub. Date: May 10, 2007

(54) Source follower capable of increasing a voltage swing of an input terminal

(75) Inventor: Yushyang Huang, Hsinchu City (TW)

Correspondence Address: BACON & THOMAS, PLLC, 625 SLATERS LANE, FOURTH FLOOR, ALEXANDRIA, VA, 22314, US

(73) Assignee: Sunext Technology Co., Ltd., Hsinchu (TW)

(21) Appl. No.: 11/594,216

(22) Filed: Nov. 8, 2006

(30) Foreign Application Priority Data
Nov. 10, 2005 (TW) 094139437

(51) Int. Cl. H03B 1/00

(52) U.S. Cl. 327/108

(57) ABSTRACT

A source follower, which can increase the voltage swing of the input terminal and overcome the insufficient driving capability of the typical source follower, includes a first current source, a first transistor, a second current source, a second transistor, a third current source and a third transistor, and uses the counteraction of the gate-source voltages of the second and third transistors to increase the voltage swing of the input terminal to the first transistor. Accordingly, the circuit is not likely to have the saturation effect on its input terminal due to the increased voltage swing of the input voltage, thereby avoiding the distortion.

### BACKGROUND OF THE INVENTION

1. Field of the Invention

The invention relates to a source follower and, more particularly, to a source follower capable of increasing a voltage swing of an input terminal.

2. Description of Related Art

Typically, a source follower functions as a voltage buffer. FIG. 1 shows a conventional circuit of a source follower, which consists of a current source I₁ and a PMOS transistor M₁. As shown in FIG. 1, the PMOS transistor M₁ has a source connected to an output terminal Vₒᵤₜ, a gate connected to an input terminal Vᵢₙ, and a drain connected to a low voltage VSS. The current source has one terminal connected to a high voltage VDD and the other terminal connected to the source of the transistor M₁.

When the source follower is in a saturation region, its input voltage Vᵢₙ can reach to a minimum Vᵢₙ₍ₘᵢₙ₎=VSS+|V_{dsat1}|−|V_{gs1}|, which can be obtained by equation (1):
Vᵢₙ+|V_{gs1}|−V_{dsat1}|>VSS,
Vᵢₙ>VSS+|V_{dsat1}|−|V_{gs1}|, (1)
where V_{dsat1} indicates a saturation voltage between the source and the drain of the transistor M₁, and V_{gs1} indicates a voltage between the source and the gate of the transistor M₁. In addition, the input voltage Vᵢₙ can reach to a maximum Vᵢₙ₍ₘₐₓ₎ of VDD−V_{I1c}−|V_{gs1}|, which can be obtained by equation (2):
Vᵢₙ+V_{I1c}+|V_{gs1}|<VDD,
Vᵢₙ<VDD−V_{I1c}−|V_{gs1}|, (2)
where V_{I1c} indicates a voltage on the current source I₁.

From equations (1) and (2), it is known that the voltage swing V_{swing} of the input voltage Vᵢₙ is:
V_{swing}=Vᵢₙ₍ₘₐₓ₎−Vᵢₙ₍ₘᵢₙ₎=(VDD−VSS)−(V_{I1c}+|V_{gs1}|).

Typically, V_{I1c} is about 0.2 V and |V_{gs1} is about 1 V. When the transistor M₁ is a native MOSFET, its voltage swing V_{swing} can be a value of (VDD−VSS)−(V_{I1c}+|V_{dsat1}|), where |V_{dsat1}| is about 0.2 V. In this case, the voltage swing of the input voltage is increased, but the source follower has an insufficient driving capability for a next level.

To overcome this problem, FIG. 2 shows an another circuit of source follower. The source follower in FIG. 2 can eliminate the problem of the insufficient driving capability, but its input voltage swing equal to (VDD−VSS)−(V_{I1c}+|V_{dsat1}|+V_{gs2}) is reduced because of the subtracted voltage V_{gs2}, where V_{gs2} is a voltage between source and gate of a transistor M₂. When VDD is 1.8 V, a low swing of an input voltage can limit the voltage magnitude of a circuit at the input terminal. In addition, when the input voltage has a slight offset, it can easily cause the circuit to present a saturation effect at the input terminal, resulting an error. Accordingly, the applications of the circuit are limited.

Therefore, it is desirable to provide an improved source follower to mitigate and/or obviate the aforementioned problems.

### SUMMARY OF THE INVENTION

The object of the invention is to provide a source follower, which can increase the voltage swing of the input terminal and overcome the insufficient driving capability of the typical source follower.

In accordance with one aspect of the invention, a source follower is provided, which functions as a voltage buffer. The source follower includes a first current source, a first transistor, a second current source, a second transistor, a third current source and a third transistor. The first current source has one terminal connected to a high voltage and the other terminal connected to an output terminal. The first transistor has a source connected to the output terminal and a gate connected to an input terminal. The second current source has one terminal connected to a low voltage and the other terminal connected to a drain of the first transistor. The second transistor has a drain connected to the output terminal and a source connected to the low voltage. The third current source has one terminal connected to the high voltage and the other terminal connected to a gate of the second transistor. The third transistor has a source connected to the gate of the second transistor, a gate connected to the drain of the first transistor, and a drain connected to the low voltage, wherein a gate-source voltage of the second transistor counteracts a gate-source voltage of the third transistor to thereby increase a voltage swing of the input terminal to the first transistor.

In accordance with another aspect of the invention, a source follower is provided, which functions as a voltage buffer. The source follower includes a first current source, a first transistor, a second current source, a second transistor, a third current source and a third transistor. The first current source has one terminal connected to a high voltage. The first transistor has a drain connected to the other terminal of the first current source, a gate connected to an input terminal, and a source connected to an output terminal. The second current source has one terminal connected to a low voltage and the other terminal connected to the output terminal. The second transistor has a drain connected to the output terminal and a source connected to the high voltage. The third current source has one terminal connected to the low voltage and the other terminal connected to a gate of the second transistor. The third transistor has a source connected to the gate of the second transistor, a gate connected to the drain of the first transistor, and a drain connected to the high voltage, wherein a gate-source voltage of the second transistor counteracts a gate-source voltage of the third transistor to thereby increase a voltage swing of the input terminal to the first transistor.

Other objects, advantages, and novel features of the invention will become more apparent from the following detailed description when taken in conjunction with the accompanying drawings.

### BRIEF DESCRIPTION OF THE DRAWINGS

FIG. 1 is a circuit diagram of a conventional source follower;

FIG. 2 is a circuit diagram of another conventional source follower;

FIG. 3 is a circuit diagram of a source follower in accordance with the invention; and

FIG. 4 is a circuit diagram of another source follower in accordance with the invention.

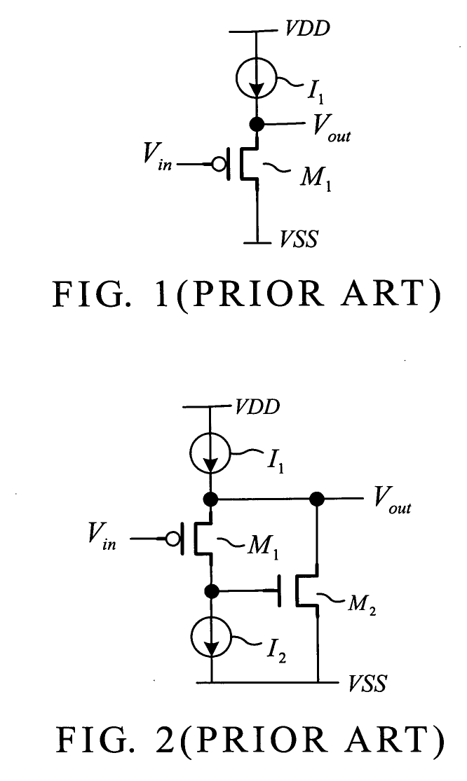

### DETAILED DESCRIPTION OF THE PREFERRED EMBODIMENT

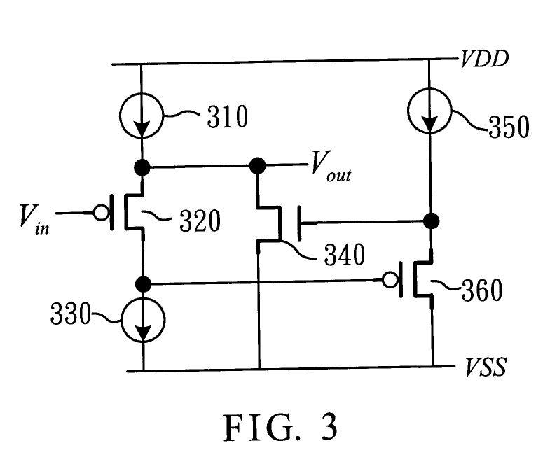

The inventive source follower can increase the voltage swing of its input terminal and overcome the problem of insufficient driving capability of the typical source follower. The source follower functions as a voltage buffer. FIG. 3 is a circuit diagram of a source follower in accordance with the invention. The source follower includes a first current source 310, a first transistor 320, a second current source 330, a second transistor 340, a third current source 350 and a third transistor 360. The first transistor 310 is PMOS transistor, the third transistor 360 is a PMOS transistor, and the second transistor 340 is an NMOS transistor. In other embodiments, the first transistor 320 can be a native PMOS transistor.

The first current source 310 has one terminal connected to a high voltage VDD and the other terminal connected to an output terminal Vₒᵤₜ. The first transistor 320 has a source connected to the output terminal Vₒᵤₜ and a gate connected to an input terminal Vᵢₙ. The second current source 330 has one terminal connected to a low voltage VSS and the other terminal connected to a drain of the first transistor 320.

The second transistor 340 has a drain connected to the output terminal Vₒᵤₜ and a source connected to the low voltage VSS. The third current source 350 has one terminal connected to the high voltage VDD and the other terminal connected to a gate of the second transistor 340. The third transistor 360 has a source connected to the gate of the second transistor 340, a gate connected to the drain of the first transistor 320, and a drain connected to the low voltage VSS, wherein a gate-source voltage V_{gs2} of the second transistor 340 counteracts a gate-source voltage V_{gs3} of the third transistor 360 to thereby increase a voltage swing of the input terminal to the first transistor 320.

The minimum Vᵢₙ₍ₘᵢₙ₎ of the input voltage Vᵢₙ of the source follower is a value of VSS+|V_{dsat1}|−|V_{gs1}|+V_{gs2}−|V_{gs3}|, which can be obtained by equation (3):
Vᵢₙ+|V_{gs1}|−|V_{dsat1}|>VSS+V_{gs2}−|V_{gs3}|,
Vᵢₙ>VSS−|V_{gs1}|+|V_{dsat1}|+V_{gs2}−|V_{gs3}|, (3)
where V_{dsat1} indicates a source-drain saturation voltage of the first transistor 320, V_{gs1} indicates a source-gate voltage of the first transistor 320, and V_{gs2} indicates a source-gate voltage of the second transistor 340. The maximum Vᵢₙ₍ₘₐₓ₎ of the input voltage Vᵢₙ is a value of VDD−V_{I1c}−|V_{gs1}|, which can be obtained by equation (4):
Vᵢₙ+V_{I1c}+|V_{gs1}|<VDD′
Vᵢₙ<VDD−V_{I1c}−|V_{gs1}|′ (4)
where V_{I1c} indicates a voltage on a current source I₁.

From equations (3) and (4), it is known that the voltage swing V_{swing} of the input voltage Vᵢₙ is:

$$\begin{matrix}{V}_{swing} = {V}_{in ( max )} - {V}_{in ( min )} \\ = ( VDD - VSS ) - ( {V}_{I 1 c} + \vert {V}_{gs 1} \vert ) .\end{matrix} \qquad ( 5 )$$

When the first transistor 320 is a native MOSFET, the voltage swing V_{swing} of the input voltage Vᵢₙ further can be reduced to (VDD−VSS)−(V_{I1c}+|V_{dsat1}|).

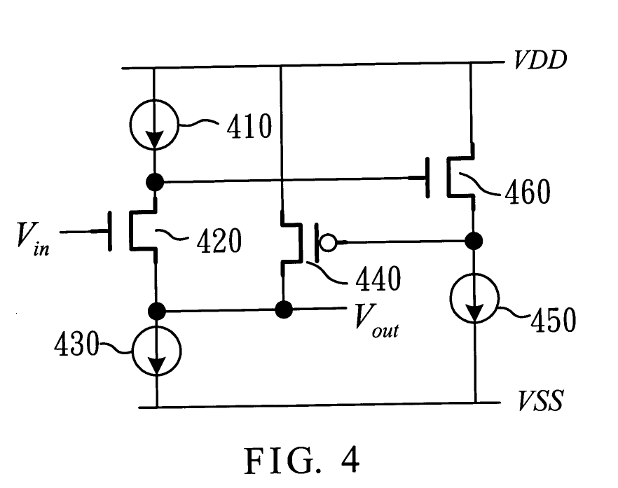

FIG. 4 is a circuit diagram of another source follower in accordance with the invention. The source follower includes a first current source 410, a first transistor 420, a second current source 430, a second transistor 440, a third current source 450 and a third transistor 460. The first transistor 420 is an NMOS transistor, the third transistor 460 is an NMOS transistor, and the second transistor 440 is a PMOS transistor. In other embodiments, the first transistor 420 can be a native NMOS transistor.

The first current source 410 has one terminal connected to a high voltage VDD. The first transistor 420 has a drain connected to the other terminal of the first current source 410, a gate connected to an input terminal Vᵢₙ, and a source connected to an output terminal Vₒᵤₜ. The second current source 430 has one terminal connected to a low voltage VSS and the other terminal connected to the output terminal Vₒᵤₜ. The second transistor 440 has a drain connected to the output terminal Vₒᵤₜ and a source connected to the high voltage VDD.

The third current source 450 has one terminal connected to the low voltage VSS and the other terminal connected to a gate of the second transistor 440. The third transistor 460 has a source connected to the gate of the second transistor 440, a gate connected to the drain of the first transistor 420, and a drain connected to the high voltage VDD, wherein a gate-source voltage V_{gs2} of the second transistor 440 counteracts a gate-source voltage V_{gs3} of the third transistor 460 to thereby increase a voltage swing of the input terminal to the first transistor 420.

In view of the foregoing, it is known that the invention uses the counteraction of the voltage V_{gs2} and the voltage V_{gs3} to increase the voltage swing of the input terminal to the first transistor and also overcome the insufficient driving capability of the typical source follower. Accordingly, when VDD equal to 1.8 V is applied to the inventive source follower, the circuit is not likely to have the saturation effect on its input terminal due to the increased voltage swing of the input voltage, thereby avoiding the distortion.

Although the present invention has been explained in relation to its preferred embodiment, it is to be understood that many other possible modifications and variations can be made without departing from the spirit and scope of the invention as hereinafter claimed.

What is claimed is:

1. A source follower, which functions as a voltage buffer, the source follower comprising:
a first current source, which has one first terminal connected to a high voltage and the other first terminal connected to an output terminal;
a first transistor, which has a first source connected to the output terminal and a first gate connected to an input terminal;
a second current source, which has one second terminal connected to a low voltage and the other second terminal connected to a first drain of the first transistor;
a second transistor, which has a second drain connected to the output terminal and a second source connected to the low voltage;
a third current source, which has one third terminal connected to the high voltage and the other third terminal connected to a second gate of the second transistor; and
a third transistor, which has a third source connected to the second gate, a third gate connected to the first drain, and a third drain connected to the low voltage;
wherein a voltage between the second gate and the second source counteracts a voltage of the third gate and the third source to thereby increase a voltage swing of the input terminal to the first transistor.

2. The source follower as claimed in claim 1, wherein the first transistor is a PMOS transistor.

3. The source follower as claimed in claim 2, wherein the PMOS transistor is a native PMOS transistor.

4. The source follower as claimed in claim 3, wherein the second transistor is an NMOS transistor.

5. The source follower as claimed in claim 4, wherein the third transistor is a PMOS transistor.

6. A source follower, which functions as a voltage buffer, the source follower comprising:
a first current source, which has one first terminal connected to a high voltage;
a first transistor, which has a first drain connected to the other first terminal of the first current source, a first gate connected to an input terminal, and a first source connected to an output terminal;
a second current source, which has one second terminal connected to a low voltage and the other second terminal connected to the output terminal;
a second transistor, which has a second drain connected to the output terminal and a second source connected to the high voltage;
a third current source, which has one third terminal connected to the low voltage and the other third terminal connected to a second gate of the second transistor; and
a third transistor, which has a third source connected to the second gate, a third gate connected to the first drain, and a third drain connected to the high voltage;
wherein a voltage between the second gate and the second source counteracts a voltage between the third gate and the third source to thereby increase a voltage swing of the input terminal to the first transistor.

7. The source follower as claimed in claim 6, wherein the first transistor is an NMOS transistor.

8. The source follower as claimed in claim 7, wherein the NMOS transistor is a native NMOS transistor.

9. The source follower as claimed in claim 8, wherein the second transistor is a PMOS transistor.

10. The source follower as claimed in claim 9, wherein the third transistor is an NMOS transistor.
